(19) United States
(12) Patent Application Publication
(10) Pub. No.: US 2003/0006494 A1
(43) Pub. Date: Jan. 9, 2003

(54) Thin profile stackable semiconductor package and method for manufacturing

(76) Inventors: Sang Ho Lee, Seoul (KR); Jun Young Yang, Seoul (KR); Ki Wook Lee, Seoul (KR); Seon Goo Lee, Kyonggi-do (KR)

Correspondence Address: WEISS & MOY PC, 4204 NORTH BROWN AVENUE, SCOTTSDALE, AZ, 85251, US

(21) Appl. No.: 10/186,407

(22) Filed: Jun. 28, 2002

(30) Foreign Application Priority Data
Jul. 3, 2001 (KR) KR 01-39441
Nov. 24, 2001 (KR) KR 01-73608

(51) Int. Cl. H01L 23/02

(52) U.S. Cl. 257/686; 257/690

(57) ABSTRACT

A semiconductor package has a substrate of an approximate planar plate comprising of an insulative layer having a plurality of land holes formed in the vicinity of an inner circumference thereof and a plurality of electrically conductive patterns formed at a surface of the insulative layer, the electrically conductive patterns comprising a plurality of bond fingers formed in the vicinity of a central portion of the insulative layer and a plurality of lands for covering the land holes connected to the bond fingers. A semiconductor die is located at a central portion of the substrate. The semiconductor die has a plurality of bond pads formed at one surface thereof. A plurality of conductive bumps is used for coupling the bond pads of the semiconductor die to the bond fingers among the electrically conductive patterns of the substrate. An encapsulating portion is formed by applying an encapsulant to the bond pads of the semiconductor die, the conductive bumps and the bond fingers of the electrically conductive patterns in order to protect them from the external environment. A plurality of terminals are coupled to each land of the substrate.

### FIELD OF THE INVENTION

This invention relates to semiconductor devices and, more specifically, to a thin profile stackable semiconductor package and a method of manufacturing the aforementioned.

### BACKGROUND OF THE INVENTION

In general, a semiconductor package is constructed in such a manner that semiconductor dies such as a single element or an integrated circuit or the like, in which every kind of electrical circuits and distributing wires are stacked, are electrically connected with a substrate and, simultaneously, connected with an external device. The semiconductor device is then sealed up with an encapsulant. The encapsulant is used to protect the components from the external environment. The encapsulant is further used to optimize and maximize electrical capability of the semiconductor die. A printed circuit board, a circuit tape, a circuit film or a lead frame or the like can be used as the substrate.

Generally, semiconductor packages are classified into a resin sealing package, a TCP (Tape Carrier Package), a glass sealing package and a metal sealing package and so forth in accordance with the kinds thereof. In particular, semiconductor packages are classified into an in-line type and a surface mount type in accordance with the mounting structures thereof. For representative in-line type semiconductor packages, there is a dual in-line package (DIP) and a pin grid array (PGA) package or the like. For representative surface mount type semiconductor packages, there is a quad flat package (QFP), a plastic leaded chip carrier (PLCC), a ceramic leaded chip carrier (CLCC) and a ball grid array (BGA) package or the like.

Recently, semiconductor packages have been developed into a light, thin, simple, miniature structure in pace with a high integration and smallness thereof. Also, since a single semiconductor package has reached the limits of the processing speed and capacity thereof, a stack type semiconductor package, in which semiconductor packages are stacked one up one another, has been developed.

This stack type semiconductor package can increase its processing speed and capacity. However, there is a problem in that it is difficulty in being mounted on products, which have been miniaturized, owing to the increase in its thickness and width.

Therefore, a need existed to provide a device and method to overcome the above problem.

### BRIEF SUMMARY OF THE INVENTION

A semiconductor package has a substrate of an approximate planar plate comprising of an insulative layer having a plurality of land holes formed in the vicinity of an inner circumference thereof and a plurality of electrically conductive patterns formed at a surface of the insulative layer, the electrically conductive patterns comprising a plurality of bond fingers formed in the vicinity of a central portion of the insulative layer and a plurality of lands for covering the land holes connected to the bond fingers. A semiconductor die is located at a central portion of the substrate. The semiconductor die has a plurality of bond pads formed at one surface thereof. A plurality of conductive bumps is used for coupling the bond pads of the semiconductor die to the bond fingers among the electrically conductive patterns of the substrate. An encapsulating portion is formed by applying an encapsulant to the bond pads of the semiconductor die, the conductive bumps and the bond fingers of the electrically conductive patterns in order to protect them from the external environment. A plurality of terminals are coupled to each land of the substrate.

The present invention is best understood by reference to the following detailed description when read in conjunction with the accompanying drawings.

### BRIEF DESCRIPTION OF THE DRAWINGS

FIG. 1 is a cross-sectional view of one embodiment of a semiconductor package According to the present invention;

FIG. 2 is a cross-sectional view of another embodiment of a semiconductor package according to the present invention;

FIG. 3 is a cross-sectional view of another further embodiment of a semiconductor package according to the present invention;

FIG. 4 is a cross-sectional view of another further embodiment of a semiconductor package according to the present invention;

FIG. 5 is a cross-sectional view of another further embodiment of a semiconductor package according to the present invention;

FIG. 6 is a cross-sectional view of another further embodiment of a semiconductor package according to the present invention;

FIG. 7 is a cross-sectional view of another further embodiment of a semiconductor package according to the present invention;

FIG. 8 is a cross-sectional view of another further embodiment of a semiconductor package according to the present invention;

FIG. 9 is a cross-sectional view of another further embodiment of a semiconductor package according to the present invention;

FIG. 10 is a cross-sectional view of another further embodiment of a semiconductor package according to the present invention; FIG. 11 is a cross-sectional view of another further embodiment of a semiconductor package according to the present invention;

FIG. 11A through FIG. 11D are plane views of substrates and spacers used in the semiconductor package of FIG. 11;

FIG. 12 is a cross-sectional view of another further embodiment of a semiconductor package according to the present invention;

FIG. 13 is a cross-sectional view of another further embodiment of a semiconductor package according to the present invention;

FIG. 14 is a cross-sectional view of another further embodiment of a semiconductor package according to the present invention;

FIG. 15A and FIG. 15B are cross-sectional views of another further embodiment of semiconductor packages according to the present invention;

FIG. 16 is a cross-sectional view of another further embodiment of a semiconductor package according to the present invention;

FIG. 17A through FIG. 17H is a flow chart for explaining a method for manufacturing one embodiment of a semiconductor package of the present invention; and

FIG. 18A through FIG. 18G is a flow chart for explaining the method for manufacturing anther embodiment of a semiconductor package of the present invention; and

FIG. 19A through FIG. 19H is a flow chart for explaining the method for manufacturing anther further embodiment of a semiconductor package of the present invention.

Common reference numerals are used throughout the drawings and detailed descriptions to indicate like elements.

### DETAILED DESCRIPTION

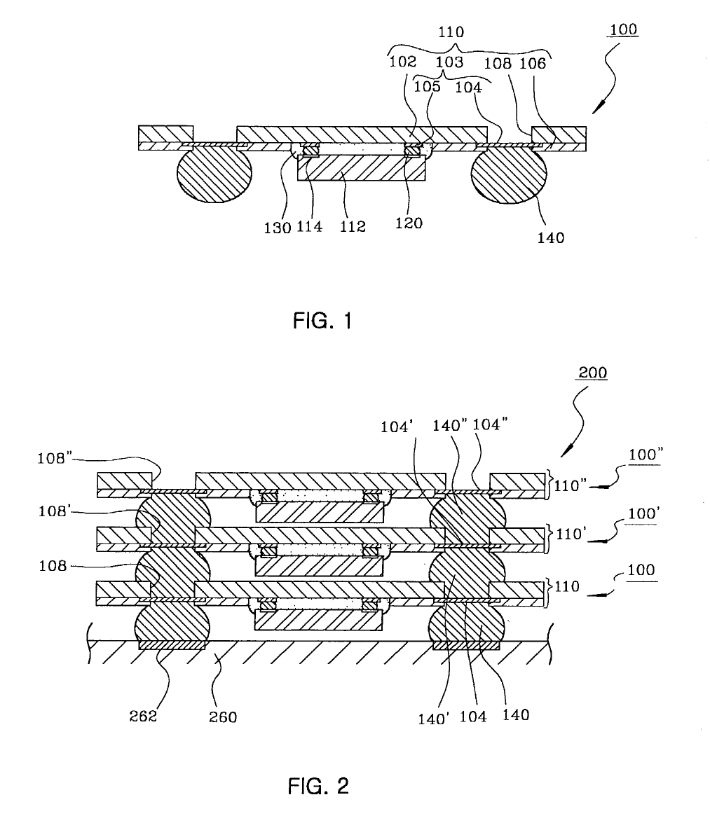

Referring to FIG. 1, a cross-sectional view of one embodiment of a semiconductor package according to the present invention is illustrated.

As shown in FIG. 1, the semiconductor package 100 including a substrate 110 of an approximately planar plate having an insulative layer 102, a plurality of electrically conductive patterns 103 and a protective layer 106, a semiconductor die 112 electrically connected to the substrate 110 and a plurality of solder balls 140 fused to the substrate 110 or the likes is provided.

More concretely, the substrate 110 includes the insulative layer 102 of an approximate planar plate having a thickness of an approximately 2 mil˜3 mil. The thickness measurement is given as an example and should not be seen as to limit the scope of the present invention. The insulative layer 102 may be formed of a plurality of different materials. For example, the insulative layer 102 of a thin plate may be a nonconductive polyimide. The insulative layer 102 made from the nonconductive polyimide has an advantage in that its electrical conductivity is very low. The insulative layer 102 has a quadrangle shape or a rectangle shape from a plan point of view. Also, a plurality of land holes 108 is formed in the vicinity of the inner circumference thereof. The land hole 108, passing through the insulative layer 102 vertically, can be formed by mechanical punching, a laser punching or an etching process and so forth. However, these are just given as examples and should not be seen as to limit the scope of the present invention. The reason for forming the land holes 108, as described above, is that the entire thickness of the semiconductor package 100 becomes thin and the solder balls 140 are accurately fused to lands 104 during fusing the solder balls 140 to the lands 104. A plurality of electrically conductive patterns 103 is formed at the bottom surface of the insulative layer 102. A chemical etching process that is designed after a thin metal layer is bonded to the insulative layer 102 forms the electrically conductive patterns 103. Each of the electrically conductive patterns 103 mainly include the lands 104 and bond fingers 105. Also, the lands 104 and the bond fingers 105 are electrically connected to each other though it is not shown in the figure. The land 104 among the electrically conductive patterns 103 covers the surface of the land hole 108 of the insulative layer 102. Moreover, the plurality of bond fingers 105 among the plurality of electrically conductive patterns 103 is formed and arranged on the bottom surface of the central portion of the insulative layer 102. The bond fingers 105 are formed at a position corresponding to bond pads 114 of the semiconductor die 112 as described later. The bond finger 105 is individually connected to the land 104, so that the electrical signals of the semiconductor die 112 are transmitted to the lands 104.

In the meantime, since the electrically conductive patterns 103 including the lands 104 and the bond fingers 105 formed at the insulative layer 102 are very thin, it can be stripped off from the insulative layer 102. Also, each of the electrically conductive patterns 103 is in contact with each other by some impact due to its narrow gap, so that a short might occur. To solve such a problem, a protective layer 106 is applied to the bottom surface of the insulative layer 12 at which the electrically conductive patterns are formed. The protective layer 106 is either called a solder mask or a solder resist. A plurality of materials may be used for the protective layer 106. Generally a nonconductive paste is used. The protective layer 106 is applied and adhered to the electrically conductive patterns 103, so that it servers to maintain the gap between each of the electrically conductive patterns. In addition, the protective layer 106 is non-conductive thereby preventing the occurrence of shorts between the electrically conductive patterns.

Of course, the protective layer 106 servers to prevent the electrically conductive patterns 103 from being separated from the insulative layer 102 and protects them from the external environments. However, the protective layer 106 should not be applied to the portions of the electrically conductive patterns 103, at which connecting terminals for connecting to the external device, for example a mother board, are formed, during the application of the protective layer 106 in order for the lands 104 and the bond fingers 105 and so forth to be exposed to the outside. Also, the surfaces of the lands 104 and the bond fingers 105 are plated so that it can prevent oxidation and improve the bonding force with solder balls as will be described later. Generally nickel/gold (Ni/Au) (not shown) are used for plating.

The semiconductor die 112 is mounted to the central portion of the bottom surface of the substrate 110. The semiconductor die 112, in which integrated circuits are formed in a silicone crystal described as a wafer, comprises a plurality of bond pads 114 for inputting and outputting electrical signals formed along the edge of the surface of the semiconductor die 112, at which the circuits are formed. The bond pads 114 and the bond fingers 105 are electrically and mechanically connected to each other by mounting the semiconductor die 112 on the substrate 110. The semiconductor die 112 can be connected to the substrate 110 by means of conductive bumps 120 after adjusting the positions of the bond pads 114 and the bond fingers 105. The conductive bump 120 is previously fused to the bond pad 114 of the semiconductor die 112 and then makes contact with the bond finger 105, so that it is perfectly adhered to between the bond pad 114 and the bond finger 105 by means of heat and pressure. However, although the bond pads 114 of the semiconductor die 112 and the bond fingers 105 among the electrically conductive patterns 103 of the substrate 110 are connected to each other by means of the conductive bumps 120, since the bonding force between the bond pads 114 and the bond fingers 105 is weak, the semiconductor die 112 can be easily separated from the substrate 110 owing to an external shock. Also, the integrated circuits formed on the surface of the semiconductor die 112 are exposed to the air outside, so that it can be damaged.

Accordingly, to prevent the above problems, an encapsulant is injected to a space between the semiconductor die 112 and the substrate 110 to form an encapsulating portion 130 of a fixed shape. The encapsulating portion 130 serves to improve the bonding force between the semiconductor die 112 and the substrate 110 and to also protect the integrated circuits formed on the semiconductor die 112 from the external environments. The encapsulant may be a variety of different materials. The material of the encapsulant may be a liquefied encap material which is injected with an epoxy mold compound (EMC) or an injector. Also, the encapsulant may be an Anisotropic Conductive Film, an Anisotropic Conductive paste, an Isotropic Conductive Film (ICF), an isotropic conductive paste, a nonconductive film or nonconductive paste and so forth. For example, in the anisotropic conductive film, hundreds of conductive grains having a diameter of about 5□ mixed with a thin adhesive film of several to tens of micro units are coated with polymer layers. If heat or pressure is applied to a predetermined region of the anisotropic conductive film, thin polymer layers of the conductive metal grains, which are included in the predetermined region, are stripped off and a plurality of conductive metal grains collide with and adhere closely to each other in order to have conductivity. Also, thin polymer layers from the remaining conductive metal grains, which are not included in the predetermined region, are maintained in an insulated status.

In the case that the anisotropic conductive film is used as the encapsulant, after the anisotropic conductive film is previously attached to the region of the substrate 110, at which the bond fingers 105 among the electrically conductive patterns are formed, or the surface of the semiconductor die 112 at which the bond pads 114 are formed, the semiconductor die 112 and the substrate 112 are bonded to each other. Of course, the positions between the conductive bumps previously fused to the bond pads 114 of the semiconductor die 112 and the bond fingers are set and then are electrically connected to each other. Accordingly, since the anisotropic conductive film is used as the encapsulant, it can protect the integrated circuits of the semiconductor die 112 from the external environment and further improves the bond force between the bond pads 114 of the semiconductor die 112 and the bond fingers 105 of the substrate 112. Here, it is unnecessary for the conductive bumps 120 to be directly and physically fused to the bond fingers 105.

In the meantime, a plurality of solder balls 140 are fused to the lands 104 among the electrically conductive patterns 103 of the substrate 110. That is, a flux having a large viscosity is dotted on each land 104 of the substrate 110 and whereby the solder balls 140 provisionally adhere to the dotted each flux. Then, if the substrate 110 having the solder ball 140 is loaded into a high temperature furnace (about 200° C.), the flux is volatilized and removed and the solder balls 140 are then melted and directly fused to the lands 104. Thereafter, if the substrate 110 is taken out from the furnace and its temperature is reduced to a normal temperature, the solder ball 140 is perfectly fused to the land 104 while keeping an approximately spherical shape owing to a surface tension. Here, the processes as described above are proceeded in a state that the semiconductor package 100 is turned up side down.

The semiconductor package 100 as described above can be in itself mounted to the external device and two or more stacked semiconductor packages can be mounted to the external device. Accordingly, this stack type semiconductor package 100 can improve its processing speed and capacity in case where memory chips are used.

Referring to FIG. 2, a cross-sectional view of another embodiment of a semiconductor package according to the present invention is illustrated. As shown in FIG. 2, a plurality of semiconductor packages 200 are stacked one up on one another.

That is, the semiconductor package (a first semiconductor package 100) as shown in FIG. 1 is mounted on an external device 260. Semiconductor packages (second and third semiconductor packages 100′ and 100″) having the same structure as the first semiconductor package 100 are stacked on the first semiconductor package 100 by turns. Namely, a solder ball 140 of the first semiconductor package 100 is fused to a connecting pad 262 of the external device 260 and a land hole 108 is formed at the bottom surface of a land 104 of a substrate 110 to which the solder ball 140 is connected. A solder ball 140′ of the second semiconductor package 100′ is fused to the top surface of the land 104 of the substrate 110 through the land hole 108 and similarly, a solder ball 140″ of the third semiconductor package 100″ is fused to the top surface of the land 104′ of the substrate 110′ through the land hole 108′, so that the stack type semiconductor package 200, in which three semiconductor packages 100, 100′ and 100″ are connected vertically, is implemented. The semiconductor package 200 can be tested before or after the stacking of the package. Accordingly, since the land holes 108 and 108′, to which the solder balls 140 and 140′ are fused, are concavely depressed and opened to the outside, the thickness of the solder ball 140 is decreased to the extent of the depressed depth of the land hole 104, thereby the entire thickness of the semiconductor package 200 can be reduced.

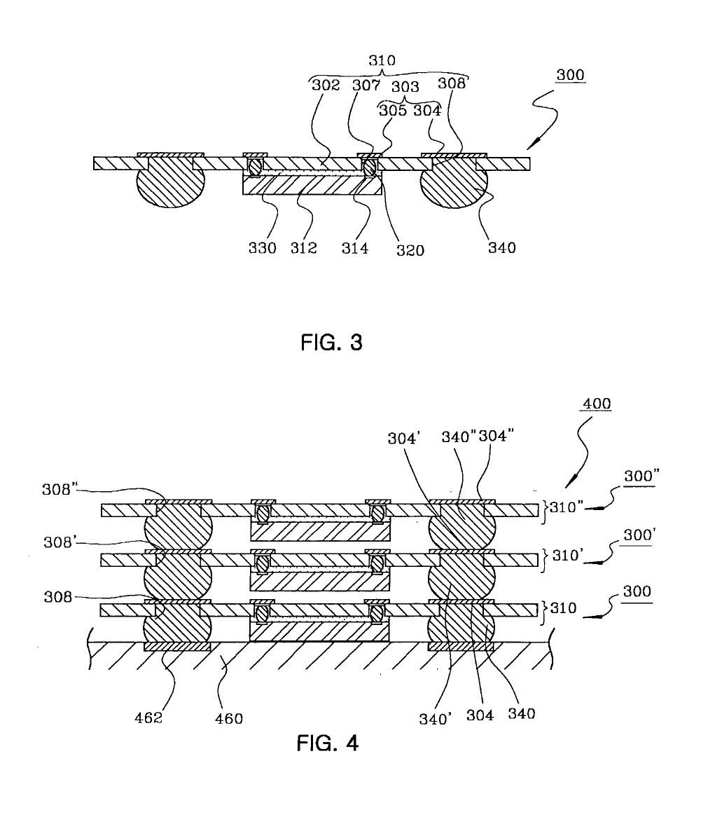

Referring to FIG. 3, a cross-sectional view of another further embodiment of a semiconductor package 300 according to the present invention is illustrated.

As shown in FIG. 3, a plurality of land holes 308 is formed at the peripheral of an insulative layer 302 of a substrate 310 and a plurality of finger holes 307 is formed at the center of the insulative layer 302. A conductive bump 320 interposed between a bond pad 314 of a semiconductor die 312 and a bond finger 305 among electrically conductive patterns 303, as described below, is inserted into and fused to the finger hole 307. The insulative layer 302 may be a nonconductive polyimide, like the semiconductor package 100 as shown in FIG. 1. Also, a plurality of electrically conductive patterns 303 is formed at the top surface of the insulative layer 302. That is, the electrically conductive patterns 303 comprise a plurality of bond fingers 305 for covering the finger holes 307 and a plurality of land 304 for covering the land holes 308. Here, the bond fingers 305 and the lands 304 are electrically connected to each other by means of connecting paths (not shown) there between.

A semiconductor die 312 is attached to a surface of the substrate 310, to which solder balls 340 are attached. The bond pad 314 of the semiconductor die 312, the finger hole 307 of the insulative layer 302 and the bond finger 305 among the electrically conductive patterns 303 are arranged at the same place, so that the semiconductor die 312 is attached to the substrate 310. Like the semiconductor package 100 as shown in FIG. 1, the conductive bumps 320 are interposed between the bond pads 314 of the semiconductor die 312 and the bond fingers 305 among the electrically conductive patterns 303, and then the semiconductor die 312 is attached to the substrate 310 by means of a thermal fusion.

An encapsulant is injected to a predetermined space between the semiconductor die 312 and the substrate 310 to form an encapsulating portion 330 of a fixed shape. The encapsulating portion 330 serves to secure a bonding reliance and an electrically connecting reliance between the semiconductor die 312 and the substrate 310. The material of the encapsulant, as described above, may be a liquefied encap material which is injected with an epoxy mold compound (EMC) or an injector, the anisotropic conductive film, the anisotropic conductive paste, the isotropic conductive film (ICF), the isotropic conductive paste, the nonconductive film or nonconductive paste and so forth. Here, the anisotropic conductive film or the anisotropic conductive paste is used as the encapsulant, so that it can improve the electrically connecting reliance between the bond pads 314 of the semiconductor die 312 and the bond fingers 305 among the electrically conductive patterns 303.

Meanwhile, solder balls 340 of the semiconductor package 300 are fused to the lands 304 through the land holes 308 which are formed at the insulative layer 302 of the substrate 310. Accordingly, the thickness of the solder ball 340 is decreased owing to the land hole 308, thereby the entire thickness of the semiconductor package 300 can be reduced.

Referring to FIG. 4, a cross-sectional view of another further embodiment of a semiconductor package 400 according to the present invention is illustrated.

As shown in FIG. 4, a plurality of semiconductor packages 300, as shown in FIG. 3, are stacked one up another. Each of semiconductor packages 300 are electrically connected to each other by means of solder balls 340′ and 340″. The solder balls 340′ and 340″ are fused through a reflow process after they are located at each land 304′ and 304″ of the semiconductor packages 340′ and 340″, so that they serve as an electrically conductive path inside the stack type semiconductor package 400.

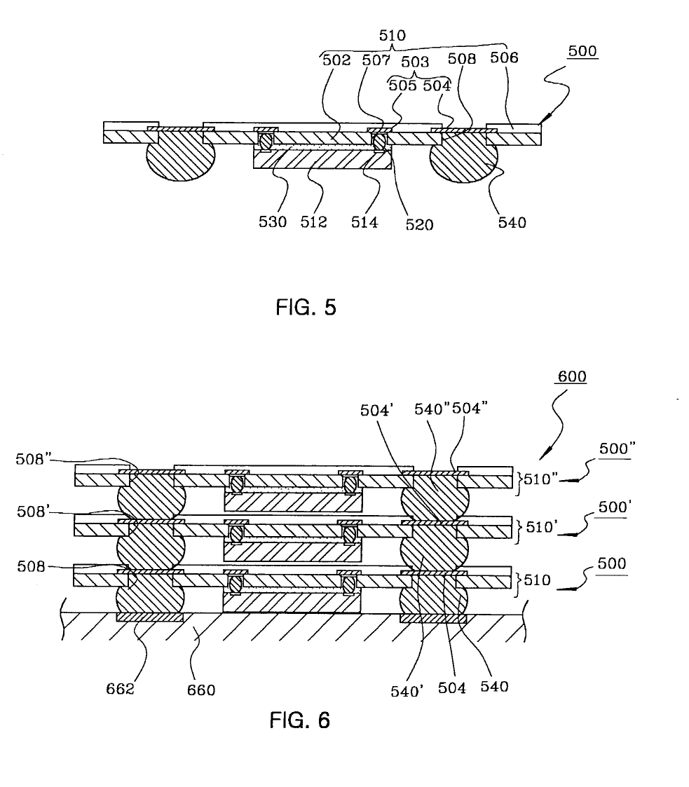

Referring to FIG. 5, a cross-sectional view of another further embodiment of a semiconductor package 500 according to the present invention is illustrated. As a semiconductor package 500 is similar to the semiconductor package 300 of FIG. 3, only differences existing there will be described herein below.

As shown in FIG. 5, a protective layer 506 is further applied to the top surface of an insulative layer 502 of a substrate 510. The protective layer 506 servers to strongly fix a plurality of electrically conductive patterns 503 having lands 504 and bond fingers 505 to the insulative layer 502 and prevents the occurrence of the short between the electrically conductive patterns 503. Of course, the protective layer 506 certainly protects the electrically conductive patterns 503 from the external environments. However, the protective layer 506 is not formed at the top surfaces of the lands 504 and land holes 508 which are formed at the insulative layer 502 of the substrate 510.

Referring to FIG. 6, a cross-sectional view of another further embodiment of a semiconductor package 600 according to the present invention is illustrated.

As shown in FIG. 6, a plurality of semiconductor packages 500, as shown in FIG. 5, are stacked one up another by turns. Each of semiconductor packages 500, 500′ and 500″ are electrically connected to each other by means of solder balls 540′ and 540″. The solder balls 540′ and 540″ are fused through a reflow process after they are located at each land 504′ and 504″ of the semiconductor packages 540′ and 540″, so that they serve as an electrically conductive path inside the stack type semiconductor package 600.

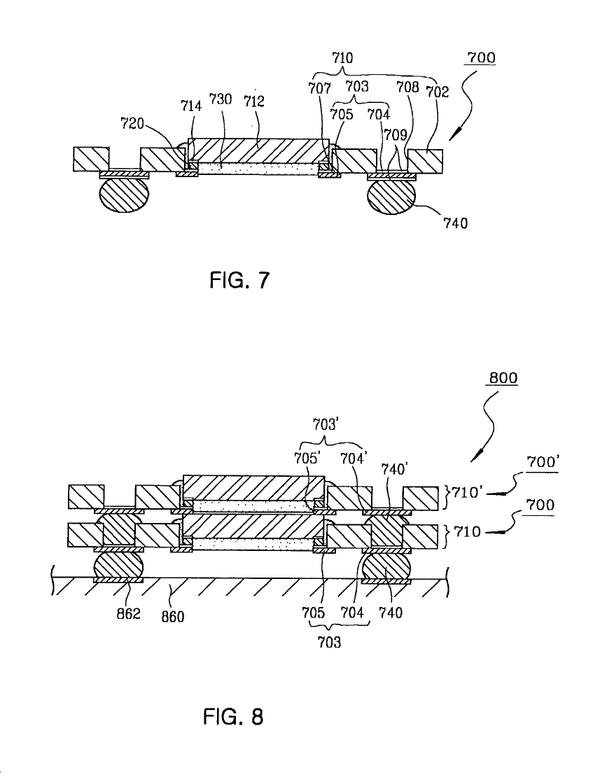

Referring to FIG. 7, a cross-sectional view of another further embodiment of a semiconductor package 700 according to the present invention is illustrated.

As shown in FIG. 7, a die cavity 707, in which a semiconductor die 712 is located, is formed at the center of an insulative layer 702 of a substrate 710. Also, a plurality of land holes 708 is formed at the periphery of the die cavity 707. A plurality of electrically conductive patterns 703 is formed at the bottom surface of the insulative layer 702 of the substrate. The electrically conductive patterns 703 comprise a plurality of lands 704 for covering the bottom surface of the land holes 708 and a plurality of bond fingers 705 extending to the inside of the die cavity 707.

Also, the semiconductor die 712 having a plurality of bond pads 714 at its bottom surface is located in the die cavity 707. Moreover, conductive bumps 720 fused to the bond pads 714 of the semiconductor die 712 are electrically and mechanically connected to the bond fingers 705.

Furthermore, a solder ball 740 is fused to one surface of the land 704 of the substrate 710.

Also, an encapsulant is injected to the inside of the die cavity 707 to form an encapsulating portion 730 of a fixed shape. The encapsulating portion serves to protect the bond pads 714 of the semiconductor die 712 and the bond fingers 705 of the substrate 710 and so forth from the external environments.

In addition, a tin(Sn)/plumbum(Pb) plating layer 709 is formed at the bottom surface of the land 704 and the solder ball 740 is attached to the plating layer 709. Here, the tin(Sn)/plumbum(Pb) plating layer 709 can be formed at both surfaces of the land 704, so that solder balls 740 can be easily attached to top and bottom surfaces of the land 704 in case of stacking two or more semiconductor packages 707 according to the present invention.

In the semiconductor package 700 according to present invention, since the solder balls 740 are partially inserted into and connected to the land holes 708 formed at the insulative layer 702 of the substrate 710, it can reduce the height of the solder ball 740 to the minimum, therefore the entire thickness of the stack type semiconductor package 700 can be reduced.

Referring to FIG. 8, a cross-sectional view of another further embodiment of a semiconductor package according to the present invention is illustrated.

As shown in FIG. 8, a semiconductor package 700′ having the same structure as the semiconductor package 700 as shown in FIG. 7 is stacked on the semiconductor package 700. That is, on the semiconductor package (a first semiconductor package 700) located at a lower part thereof, the other semiconductor package (a second semiconductor package 700′) is stacked. The semiconductor packages 700 and 700′ are electrically connected to the external device 860 by means of the solder balls 740 and 740′.

More concretely, the first semiconductor package 700 as shown in FIG. 7 is mounted on the external device 860. A solder ball 740 of the first semiconductor package 700 is fused to a connecting pad 862 of the external device 860. Also, the second semiconductor package 700′ having the same structure as the first semiconductor package 700 is stacked on the first semiconductor package 100. The solder ball 740′ of the second semiconductor package 700′ is arranged inside the land hole 708 of the first semiconductor package 700. Thereafter, the solder balls 740′ of the second semiconductor package 700 are melted through the reflow process, so that the lands 704 and 704′ of the first and second semiconductor packages 700 and 700′ are connected to each other and adhered to each other at normal temperature. Accordingly, a plurality of semiconductor packages 700 having the same structure can be continuously stacked up another in the above method

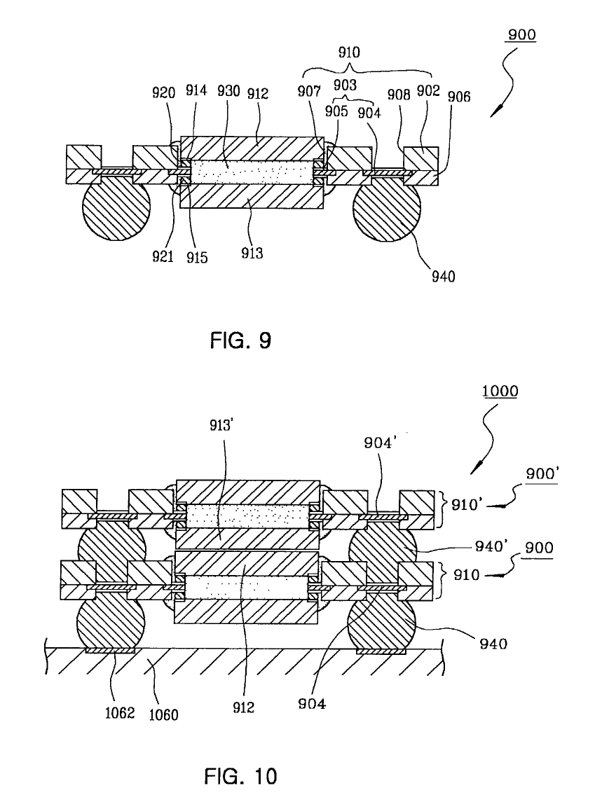

Referring to FIG. 9, a cross-sectional view of another further embodiment of a semiconductor package 900 according to the present invention is illustrated.

As shown in FIG. 9, a first semiconductor die 912 is attached to one surface of a bond finger 905 opposed to another surface of the bond finger 905 at which a second semiconductor die 913 is formed. That is, the second semiconductor die 913 formed at its lower part, like the first semiconductor die 912 formed at its upper part, is electrically connected to the bond fingers 905 by means of conductive bumps 921 there between. In the semiconductor packages 100-800 according to the above embodiments of the present invention, only a single semiconductor die is located at the substrate. However, in the semiconductor package 900 according to this embodiment of the present invention, two semiconductor dies 912 and 913 are attached to the single substrate 910. Also, an encapsulant is injected to an inside and circumference of a space between the first semiconductor die 912 attached inside the insulative layer 902 and the second semiconductor die 913 attached inside the protective layer 906 to form an encapsulating portion 930 of a fixed shape. The encapsulating portion serves to prevent the intrusion of the extraneous matter into the space and strength the adhering force of the semiconductor dies 912 and 913 in addition to protecting the two semiconductor dies 912 and 913.

Referring to FIG. 10, a cross-sectional view of another further embodiment of a semiconductor package 1000 according to the present invention is illustrated.

As shown in FIG. 10, two semiconductor packages 900 and 900′, as described above, are stacked vertically. The semiconductor package 900 (a first semiconductor package) formed at its lower part for mounting to an external device 1060 is electrically connected to the external device 1060 by means of solder balls 940 attached to lands 904. A second semiconductor package 900′ having the same structure as the first semiconductor package 900 is stacked on the first semiconductor package 900. The first semiconductor package 900 and the second semiconductor package 900′ are connected to each other by means of solder balls 940′ there between. The solder ball 940′ is fused at a high temperature and then, the first and second semiconductor packages 900 and 900′ are adhered to each other by means of the solder ball 904′ at normal temperature. The solder ball 940′ servers as a connector during the stacking of two or more semiconductor packages 900 and 900′ and as an electrical connector between semiconductor packages, like the above embodiments according to the present invention.

Here, it is preferred that the semiconductor dies 912 and 913′ are not contacted with each other during stacking of the first and second semiconductor packages 900 and 900′. If the semiconductor dies having high heat discharge characteristics are closely contacted with each other, its heat discharge path can be blocked, thereby lowering its efficiency.

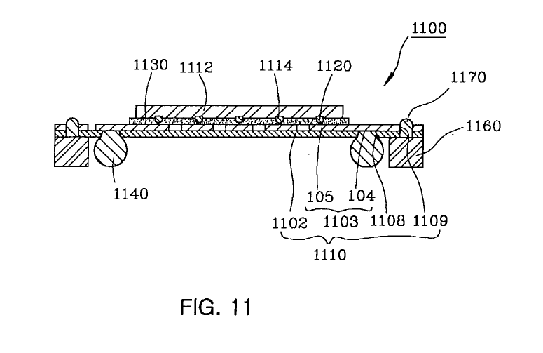

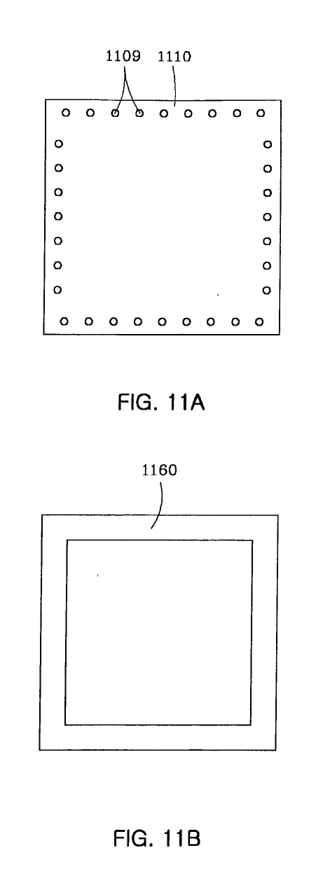

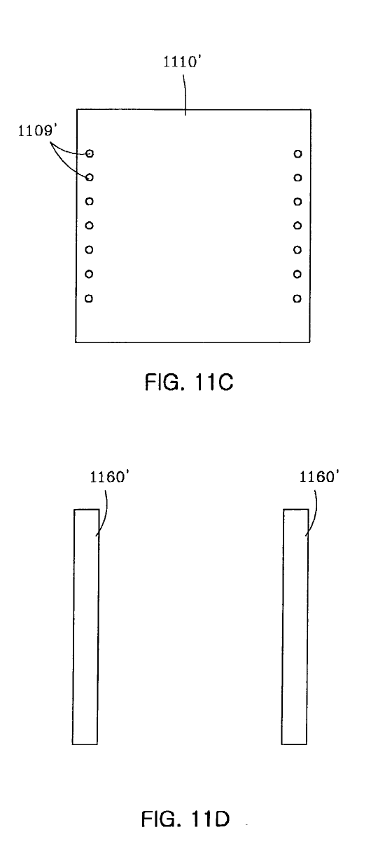

Referring to FIG. 11, a cross-sectional view of another further embodiment of a semiconductor package 1100 according to the present invention is illustrated.

As shown in FIG. 11, a spacer 1160 having a predetermined thickness is further fixed to an inner circumference of a substrate 1110 in order that the semiconductor package 1100 is not easily bent. The spacer 1160 as an electrical conductor can be formed at the bottom surface of the inner circumference of the substrate 1110. The material of the spacer 1160 may be any electrical conductor such as a conventional copper (Cu), aluminum (Al) or its equivalent. However, these are given just as examples and should not be seen as to limit the scope of the present invention. Also, a plurality of spacer holes 1109 is formed at the substrate 1110 corresponding to the spacer 1160. A solder 1170 are fused to the spacer holes 1109 of the substrate 1110 in order to fix the spacer 1160 to the bottom surface of the substrate 1110, in a stable manner.

Here, the spacer 1160 is electrically connected to a specific conductive patterns 1103 by means of the solder 1170. It is preferred that the specific conductive patterns 1103 is used for ground or power. That is, since the spacer 1160 of the electrical conductor is utilized for ground or power, it can use many solder balls 1140 for signaling in comparison with the prior art.

Also, it is preferred that the thickness of the spacer 1160 is the same as that of the solder ball 1140 or is a little smaller than that of the solder ball 1140. That is, if the thickness of the spacer 1160 is larger than that of the solder ball 1140, it is difficult for the solder balls 1140 to be adequately connected to the external device at a later time.

Referring to FIG. 11A through FIG. 11D, top plane views of substrates 1110 and 1110′ and spacers 1160 and 1160′ used in the semiconductor package 1100 of FIG. 11 are illustrated. Here, the electrically conductive patterns or the likes are not shown in the drawings.

Firstly, as shown in FIG. 11A and FIG. 11B, the spacer hole 1109 of a rectangular line shape can be formed along the circumference of the substrate 1110. Of course, it is preferred that the spacer 1160 is also, a rectangular line shape.

Also, as shown in FIG. 11C and FIG. 11D, the spacer holes 1109′ can be formed at only two opposed sides along the circumference of the substrate 1110′. Here, preferably, the spacer 1160′ is formed in two straight lines.

Accordingly, the spacer allows the rigidity of the substrate to be increased at its periphery and the semiconductor package 1100 to be easily treated during or after the fabricating process. That is, the bend of the semiconductor package 1100 can be prevented. Also, since the spacer 1160 of the electrical conductor can be utilized for ground or power, it can increase the number of solder balls for signaling.

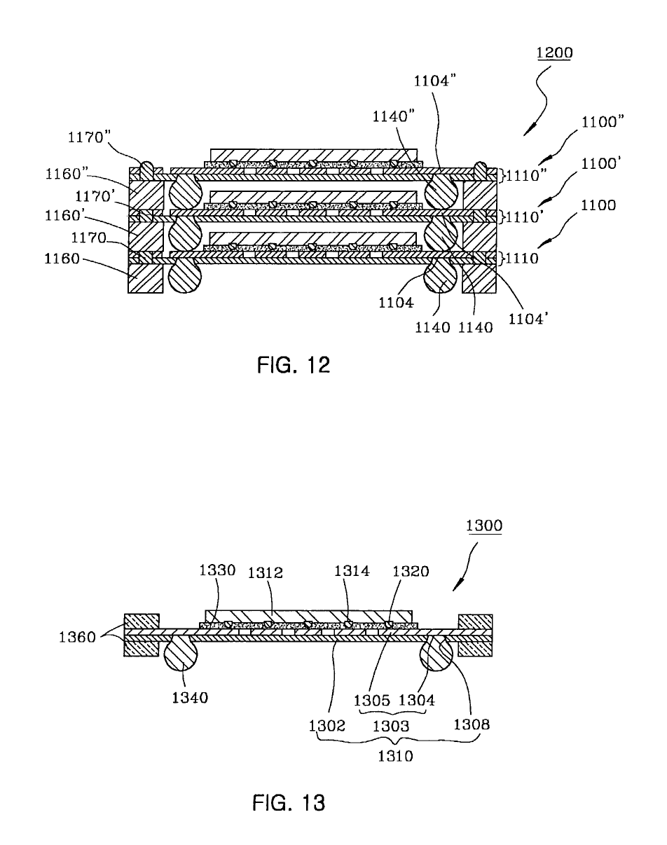

Referring to FIG. 12, a cross-sectional view of another further embodiment of a semiconductor package 1200 according to the present invention is illustrated.

As shown in FIG. 12, a plurality of semiconductor packages 1100 can be stacked vertically. At this time, solder ball 1140′ of the semiconductor package 1100′ formed at its upper part that is electrically connected to a land 1103 among the electrically conductive patterns of the semiconductor package 1100 formed at its lower part. Also, upper spacer 1160′ is electrically and mechanically fixed through a solder 1170 formed at the lower part of the upper spacer. Accordingly, in the semiconductor package 1200 as described above, it can increase the rigidity of the substrate and prevent the transformation of the stacked package owing to the spacers 1160, 1160′ and 1160″ formed at the inner circumference of the substrate 1110, 1110′ and 1110″.

Referring to FIG. 13, a cross-sectional view of another further embodiment of a semiconductor package according to the present invention is illustrated.

As shown in FIG. 13, since the structure and the mutual organic relation of the semiconductor package 1300 comprising a substrate 1310, an encapsulating portion 1330 and a semiconductor die 1312 and so forth as shown in FIG. 13 is similar to the semiconductor package 1100 of FIG. 11, only differences existing there will be described herein below.

Here, a nonconductor of electricity can be used as the spacer 1360 of the semiconductor package 1300. That is, the material of the spacer 1360 may be any nonconductor of electricity such as a conventional dry film, adhesive film or its equivalent. It is preferred that the spacers 1360 are formed at the top and bottom surfaces of the periphery of the substrate 1310 so as to secure the rigidity of the substrate. However, the present invention is not limited to the spacers formed at top and bottom surfaces of the substrate. Also, it is preferred that the thickness of the spacer 1360 is the same as that of the solder ball 1140 or is a little smaller than that of the solder ball 1340.

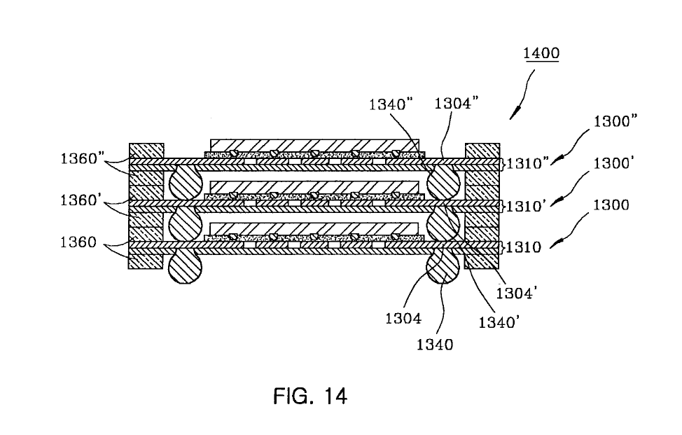

Referring to FIG. 14, a cross-sectional view of another further embodiment of a semiconductor package 1400 according to the present invention is illustrated.

As shown in FIG. 14, a solder ball 1340′ of the semiconductor package 1300′ formed at its upper part is electrically connected to a land 1303 among the electrically conductive patterns of the semiconductor package 1300 formed at its lower part. Also, an upper spacer 1360′ is bonded to a lower spacer 1360. Here, it is preferred that the upper and lower spacers 1360 and 1360′ are bonded to each other by means of an adhesive tape or its equivalents there between. Of course, the upper and lower spacers 1360 and 1360′ can be easily bonded to each other by means of a double-faced tape or its equivalents there between.

Accordingly, in the semiconductor package 1400 as described above, it can increase the rigidity of the substrate and prevent the transformation of the stacked package 1400 owing to spacers 1360, 1360′ and 1360″ formed at the circumference of the substrate 1310, 1310′ and 1310″.

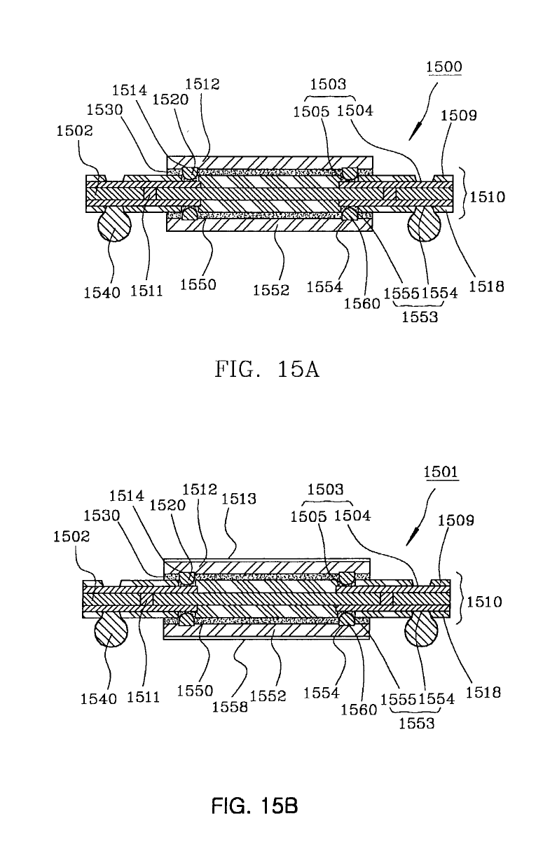

Referring to FIG. 15A, a cross-sectional view of another further embodiment of a semiconductor package 1500 according to the present invention is illustrated.

As shown in FIG. 15, the semiconductor package 1500 comprising a substrate 1510 of an approximately planar plate having an insulative layer 1502 is provided. A plurality of electrically conductive patterns 1503 and 1553 are formed at both surfaces of the insulative layer 1502. That is, the electrically conductive patterns 1503 having bond fingers 1505 and lands 1504 are formed at one surface of the insulative layer 1502 and the other electrically conductive patterns 1553 having bond fingers 1555 and lands 1554 are formed at the other surface of the insulative layer 1502. The electrically conductive patterns 1503 and 1553 are electrically connected to each other by means of electrically conductive vias 1511. The remaining regions of the electrically conductive patterns 1503 and 1553 excepting the bond fingers 1505 and 1555 and the lands 1504 and 1554 are coated with an insulating cover that coats 1509 and 1518.

In the meantime, a first semiconductor die 1512 is electrically connected to the bond fingers 1505 formed at one surface of the substrate 1510 by means of conductive bumps 1520. Of course, the conductive bumps 1520 are fused to bond pads 1514 formed at the first semiconductor die 1512.

Also, a second semiconductor die 1552 is electrically connected to the bond fingers 1555 formed at the other surface of the substrate 1510 by means of conductive bumps 1560. Of course, the conductive bumps 1560 are fused to bond pads 1554 formed at the second semiconductor die 1552.

Moreover, encapsulants are injected to spaces between the semiconductor dies 1512 and 1552 and the substrate 1510 to form encapsulating portions 1530 and 1550 of a fixed shape. The encapsulating portion serves to improve the bonding force between the semiconductor dies 1512 and 1552 and the substrate 1510 and protects the integrated circuits formed on the semiconductor dies from the external environments. The material of the encapsulant may be a liquefied encap material which is injected with an epoxy mold compound (EMC) or an injector. Also, the encapsulant may be an Anisotropic Conductive Film, an Anisotropic Conductive paste, nonconductive film or nonconductive paste and so forth.

Continuously, the solder balls 1540 are fused to each of lands 1554 of electrically conductive patterns 1553, thereby the semiconductor package can be easily mounted on the external device. Of course, the solder balls 1540 can be fused to other lands 1504 of the substrate. 1510.

Referring to FIG. 15B, a cross-sectional view of another further embodiment of a semiconductor package according to the present invention is illustrated. Since the semiconductor package 1501 is similar to the semiconductor package 1500 of FIG. 15A, it will be described around those differences existing herein below.

As shown in FIG. 15B, conductive or nonconductive die protective layers 1513 and 1558 are formed on back sides of the first semiconductor die 1512 and the second semiconductor die 1552, that is, on the surfaces of the semiconductor dies 1512 and 1552 where the bond pads 1514 and 1554 are not formed, respectively. It is preferred that the die protective layers 1513 and 1558 are formed on the back side of the wafer by means of a normal spin coating manner. However, the die protective layers 1513 and 1558 also, can be formed after sawing the semiconductor dies from the wafer into individual pieces. The die protective layers 1513 and 1558 server to prevent the damage of the integrated circuits formed on the front side of very thin semiconductor die due to a transmission of a laser during the laser marking process of semiconductor package. Also, the die protective layer 1513 and 1558 server to improve the quality of the marking process and to handle easily. These die protective layers 1513 and 1558 can be equally applied to all embodiments of the present invention and the present invention is not limited to this embodiment.

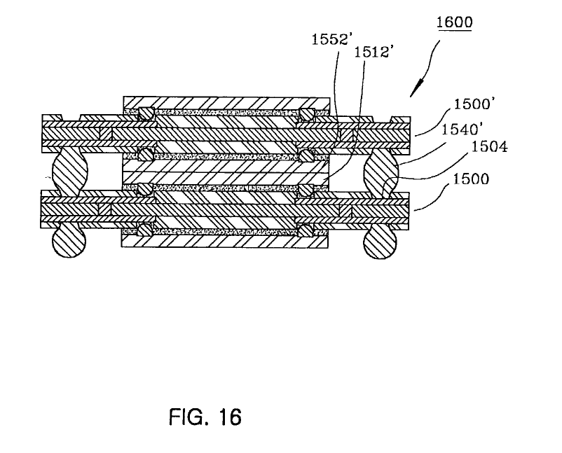

Referring to FIG. 16, a cross-sectional view of another further embodiment of a semiconductor package 1600 according to the present invention is illustrated.

As shown in FIG. 16, two semiconductor packages 1500 and 1500′, as described above, can be stacked vertically. Here, a solder ball 1540′ of the semiconductor package 1500′ formed at its upper part is electrically connected to the top surface of a land 1504 among the electrically conductive patterns of the semiconductor package 1500 formed at its lower part. Also, the semiconductor die 1552′ of the upper semiconductor package 1500′ and the semiconductor die 1512′ of the lower semiconductor package 1500 can be contacted with or separated from each other.

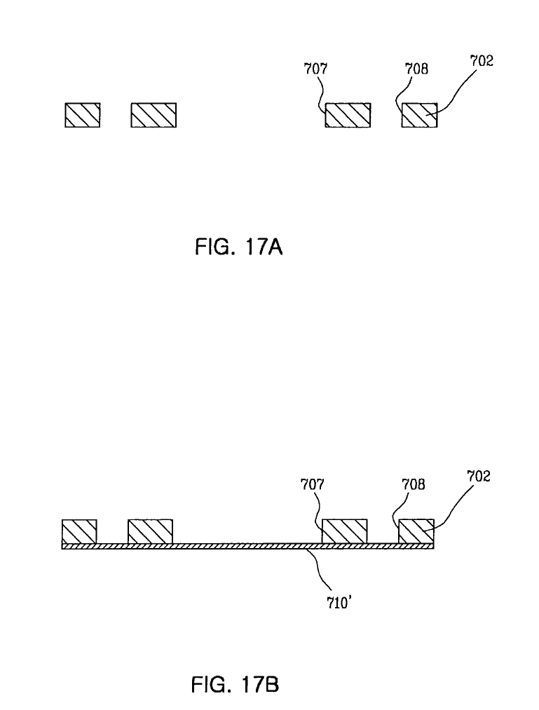

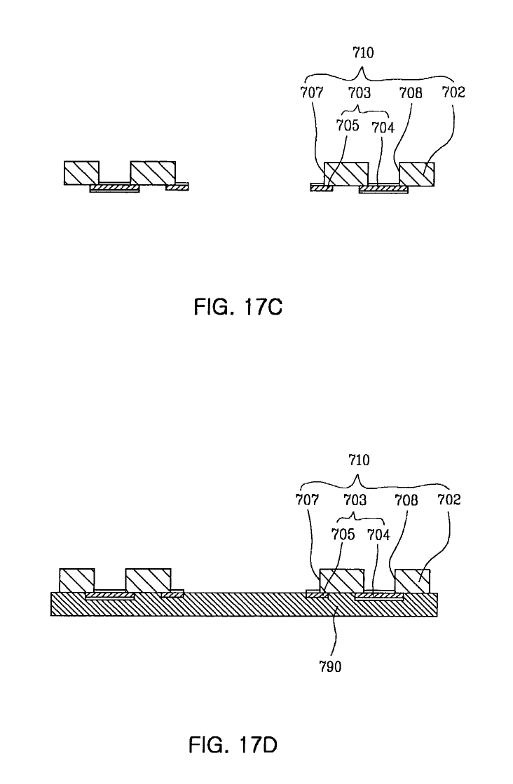

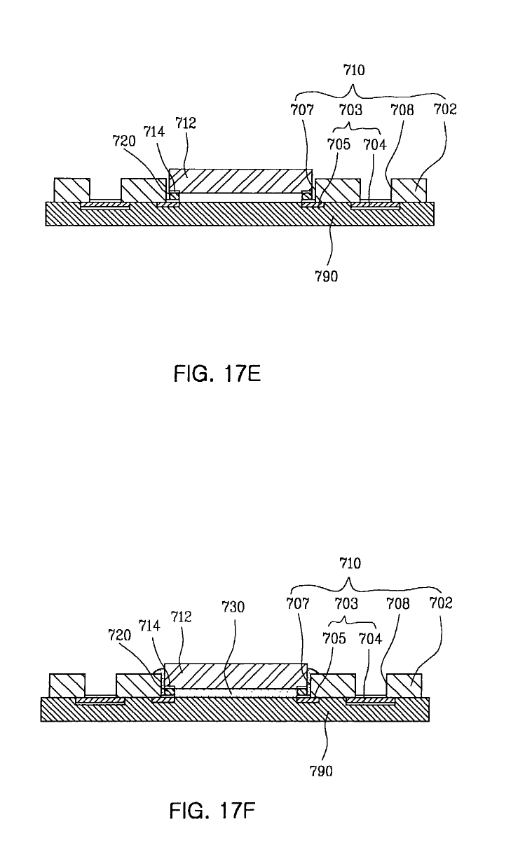

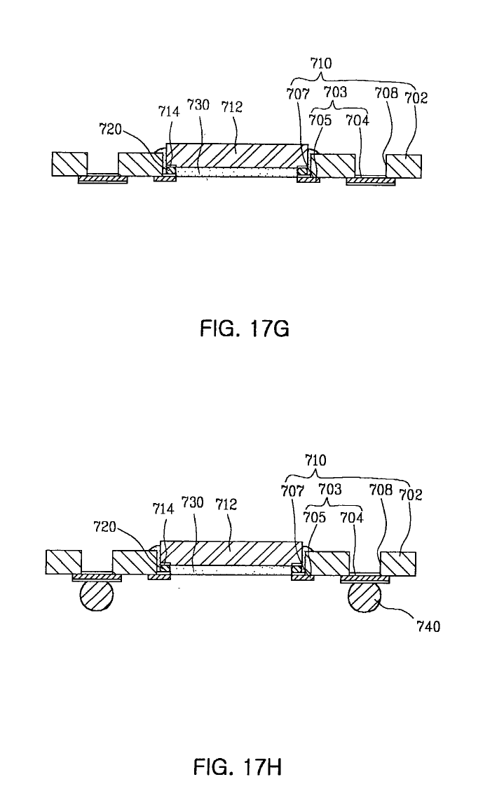

Referring to FIG. 17A through FIG. 17H, the process flow for constructing the embodiment illustrated by FIG. 7 is discussed.

Firstly, as shown in FIG. 17A, an insulative layer 702 of an approximate planar plate comprising a die cavity 707 formed at its center and a plurality of land holes 708 formed at the periphery of the die cavity 707 is provided.

Continuously, as shown in FIG. 17B, a conductive thin layer 710′ is bonded to the insulative layer 702 in order to cover one surface of the insulative layer 702, the die cavity 707 and the land holes 708.

On succession, as shown in FIG. 17C, the conductive thin layer 710′ is etched in a predetermined shape so as to form a plurality of lands 704 for covering the land holes 708 and a plurality of bond fingers 705 extending to the inside of the die cavity 707, whereby forming a substrate 710 having a plurality of electrically conductive patterns 703.

Successively, as shown in FIG. 17D, an adhesive tape 790 of an approximately planar plate is bonded to one surface of the substrate 710 at which the electrically conductive patterns 703 are formed.

Subsequently, as shown in FIG. 17E, a semiconductor die 712 having a plurality of bond pads 714 is located inside the die cavity 707 of the substrate 710. Here, conductive bumps 720 are fused to the bond pads 714 of the semiconductor die 712 and then, the conductive bumps are fused to the bond fingers 705.

Continuously, as shown in FIG. 17F, an encapsulant is injected to the inside of the die cavity 707 to form an encapsulating portion 730 of a fixed shape, so that it serves to protect the bond pads 714 of the semiconductor die 712, the conductive bumps 720 and the bond fingers 705 of the substrate 710 from the external environments.

Successively, as shown in FIG. 17G, the adhesive tape is removed from the substrate 710.

Finally, as shown in FIG. 17H, a plurality of solder balls 740 is fused to the lands 704 of the substrate 710 in order that they can be mounted to the external device.

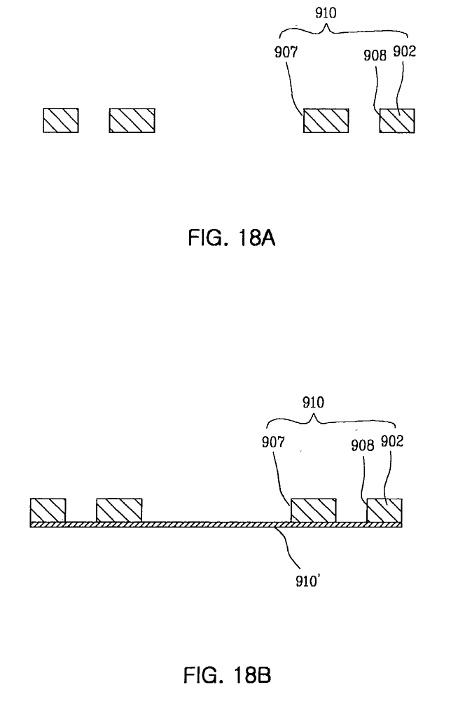

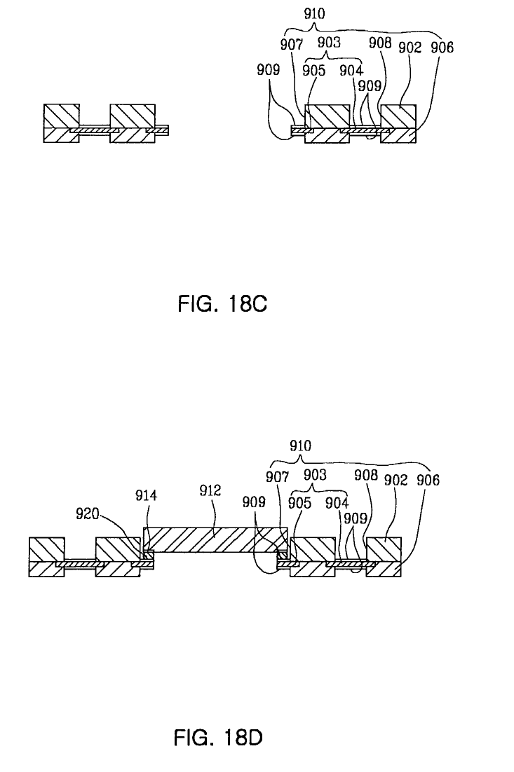

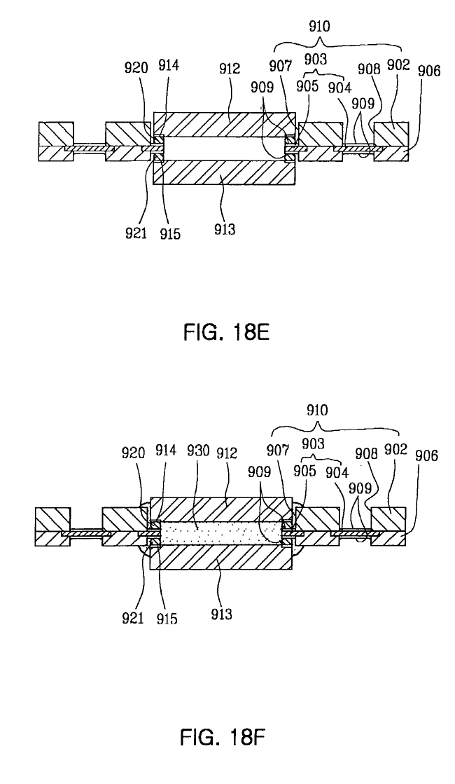

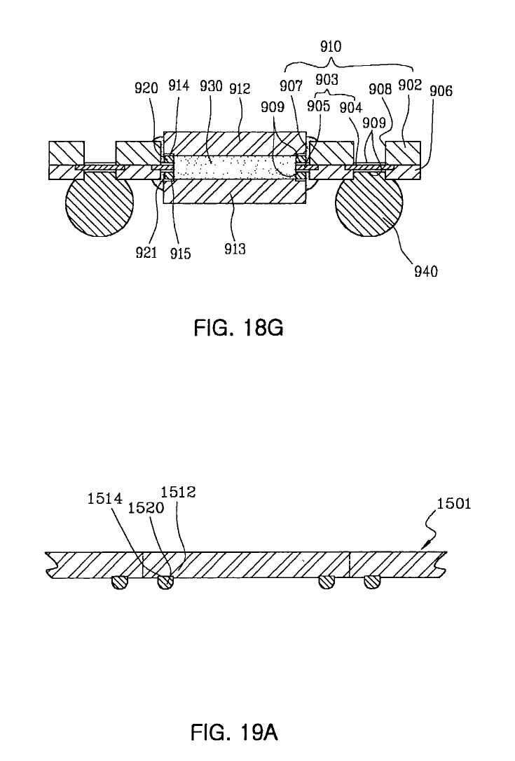

Referring to FIG. 18A through FIG. 18G, the process flow for constructing the embodiment illustrated by FIG. 9 is discussed.

Firstly, as shown in FIG. 18A, an insulative layer 902 of an approximate planar plate comprising a die cavity 907 formed at its center and a plurality of land holes 908 formed at the periphery of the die cavity 907 is provided.

Continuously, as shown in FIG. 18B, a conductive thin layer 910′ is bonded to the insulative layer 902 in order to cover one surface of the insulative layer 902, the die cavity 907 and the land holes 908.

On succession, as shown in FIG. 18C, the conductive thin layer 910′ is etched in a predetermined shape so as to form a plurality of electrically conductive patterns 903 comprising a plurality of lands 904 for covering the land holes 908 and a plurality of bond fingers 905 extending to the inside of the die cavity 907. Also, a protective layer 906 is formed at the bottom surface of the insulative layer 902 in order that the lands 904 and the bond fingers 905 are exposed to outside. Accordingly, it constitutes a substrate 910 of an approximate planar plate comprising the electrically conductive patterns 903 and the protective layer 906 or the like. Here, plating layers 909 of a predetermined thickness are formed on the surfaces of the lands 904 and the bond fingers 909 by plating with a nickel (Ni)/tin (Sn) or the like. Such forming is merely an option for those who is related in the art.

Subsequently, as shown in FIG. 18D, a semiconductor die 912 having a plurality of bond pads 914 is located inside the die cavity 907 of the substrate 910. Here, conductive bumps 920 are fused to the bond pads 914 of the semiconductor die 912 and then, the conductive bumps 920 are fused to top surfaces of the bond fingers 905.

Continuously, as shown in FIG. 18E, the other semiconductor die 913 having a plurality of bond pads 915 is located at the bottom surface of the substrate 910 corresponding to the semiconductor die 912 located inside the die cavity 907 of the substrate 910. Here, conductive bumps 921 are fused to the bond pads 915 of the semiconductor die 913 and then, the conductive bumps 921 are fused to bottom surfaces of the bond fingers 905.

Also, the order of fusing the semiconductor dies 912 and 913 can be changed. In the case of forming the plating layer 909 on the bond fingers 909 as described above, it is desirable to use a normal reflow manner. Also, in the case that the plating layer 909 is not formed, it is desirable to use a normal thermo compressing manner, thermal ultra-sonic manner, pulse heating manner and constant-heating manner and so forth.

Continuously, as shown in FIG. 18F, an encapsulant is injected to the inside of the die cavity 907 to form an encapsulating portion 930 of a fixed shape, so that it serves to protect the bond pads 914 and 915 of the semiconductor dies 912 and 913, the conductive bumps 920 and 921, and the bond fingers 905 of the substrate 910 from the external environment.

Here, the encapsulating portion 930 can be formed through two steps. That is, one semiconductor die 912 is fused on the bond fingers 905 to constitute a part of the encapsulating portion and then, the other semiconductor die 913 is fused on the bond fingers 905 to constitute the remaining encapsulating portion.

Finally, as shown in FIG. 18G, a plurality of solder balls 940 is fused to the lands 904 of the substrate 910 in order that they can be mounted to the external device.

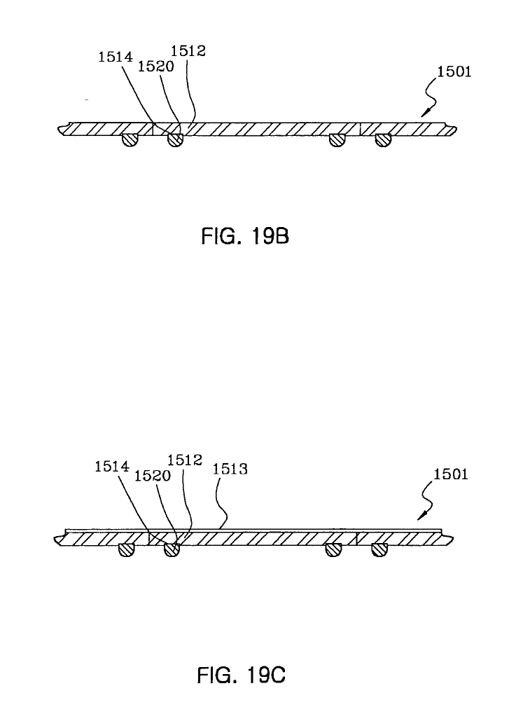

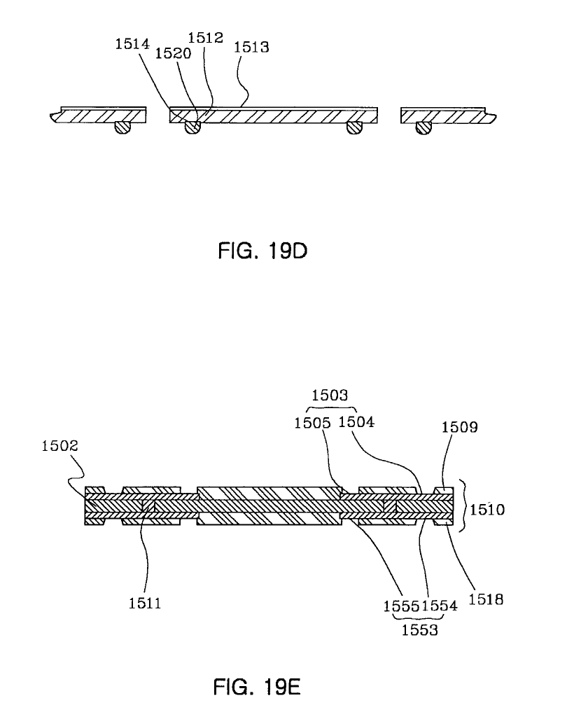

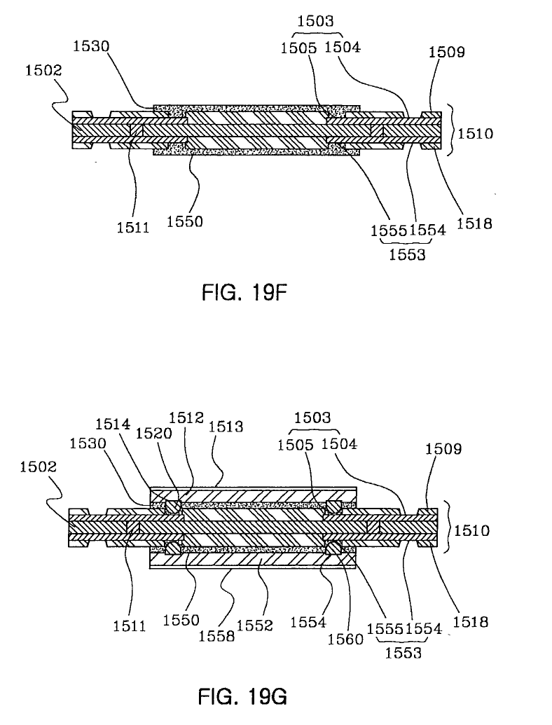

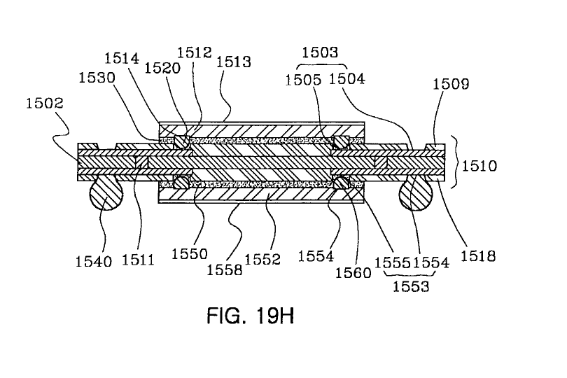

Referring to FIG. 19A through FIG. 19H, the process flow for constructing the embodiment illustrated by FIG. 15A and FIG. 15B is discussed.

Firstly, as shown in FIG. 19A, a wafer 1501 having a plurality of semiconductor dies 1512 is provided. A plurality of conductive bumps 1520 is formed at the semiconductor dies 1512, respectively. That is, the conductive bumps 1520, such as a gold (Au), a silver (Ag) or a solder (Sn/Pb), are the bond pads 1514 of each semiconductor die 1512.

Here, the conductive bump 1520 may be a stud bump using the gold wire. At this time, a leveling process also, may be performed, thereby the bumps are all the same height.

On succession, as shown in FIG. 19B, by grinding the back side of the wafer 1501 at a predetermined thickness, the thickness of each semiconductor die 1512 of the wafer 1501 is minimized.

Continuously, as shown in FIG. 19C, a die protective layer 1513 of a predetermined thickness is formed on the back side of the wafer 1501 by means of the spin coating manner. The die protective layer 1513 may be a conductive material or nonconductive material. The die protective layer 1513 servers to prevent the damage of the integrated circuits due to a transmission of a laser during the laser marking process of the semiconductor package, to improve the quality of the marking process and to handle easily.

Subsequently, as shown in FIG. 19D, each of the semiconductor dies 1512 is sawed and separated from the wafer.

On succession, as shown in FIG. 19E, a substrate 1510 of an approximately planar plate having an insulative layer 1502 is provided. A plurality of electrically conductive patterns 1503 and 1553 are formed at both surfaces of the insulative layer 1502. That is, the electrically conductive patterns 1503 having bond fingers 1505 and lands 1504 are formed at one surface of the insulative layer 1502 and the other electrically conductive patterns 1553 having bond fingers 1555 and lands 1554 are formed at the other surface of the insulative layer 1502. The electrically conductive patterns 1503 and 1553 are electrically connected to each other by means of electrically conductive vias 1511. The remaining regions of the electrically conductive patterns 1503 and 1553 excepting the bond fingers 1505 and 1555 and the lands 1504 and 1554 are coated with an insulating cover coats 1509 and 1518.

Continuously, as shown in FIG. 19F, an encapsulant is injected to spaces between the semiconductor dies 1512 and 1552 and the substrate 1510 to form encapsulating portions 1530 and 1550 of a fixed shape. The material of the encapsulant may be a liquefied encap material which is injected with an epoxy mold compound (EMC) or an injector. Also, the encapsulant may be an Anisotropic Conductive Film, an Anisotropic Conductive paste, an Isotropic Conductive Film (ICF), an isotropic conductive paste, a nonconductive film or nonconductive paste and so forth.

Here, in the case of using the epoxy mold compound (EMC) or the liquefied encap material as the encapsulating material, a semiconductor die bonding process mentioned below is previously performed and then, the encapsulating process is performed.

Subsequently, as shown in FIG. 19G, the first semiconductor die 1512 is electrically connected to the bond fingers 1505 formed at one surface of the substrate 1510 by means of conductive bumps 1520. Also, the second semiconductor die 1552 is electrically connected to the bond fingers 1555 formed at the other surface of the substrate 1510 by means of conductive bumps 1560.

Finally, as shown in FIG. 19H, the solder balls 1540 are fused to each of lands 1554 of electrically conductive patterns 1553, thereby the semiconductor package can be easily mounted on the external device. Of course, the solder balls 1540 can be fused to other lands 1504 of the substrate. 1510.

This disclosure provides exemplary embodiments of the present invention. The scope of the present invention is not limited by these exemplary embodiments. Numerous variations, whether explicitly provided for by the specification or implied by the specification, such as variations in structure, dimension, type of material and manufacturing process may be implemented by one of skill in the art in view of this disclosure.

What is claimed is:

1. A semiconductor package comprising:
a substrate of an approximate planar plate comprising of an insulative layer having a plurality of land holes formed in the vicinity of an inner circumference thereof and a plurality of electrically conductive patterns formed at a surface of the insulative layer, the electrically conductive patterns comprising a plurality of bond fingers formed in the vicinity of a central portion of the insulative layer and a plurality of lands for covering the land holes connected to the bond fingers;
a semiconductor die located at a central portion of the substrate; the semiconductor die having a plurality of bond pads formed at one surface thereof;
a plurality of conductive bumps for coupling the bond pads of the semiconductor die to the bond fingers among the electrically conductive patterns of the substrate;
an encapsulating portion formed by applying an encapsulant to the bond pads of the semiconductor die, the conductive bumps and the bond fingers of the electrically conductive; and
a plurality of terminals fused to each land of the substrate.

2. The semiconductor package of claim 1 wherein the ecapsulant is selected from a group comprising of: an epoxy mold compound (EMC) a liquefied encap material, an anisotropic conductive film (ACF), an anisotropic conductive paste, an isotropic conductive film (ICF), an isotropic conductive paste, a nonconductive film, a nonconductive paste, and combinations thereof.

3. The semiconductor package of claim 1 wherein the electrically conductive patterns are formed at a bottom surface of the insulative layer.

4. The semiconductor package of claim 3 further comprising a protective layer coupled to the bottom surface of the insulative layer.

5. The semiconductor package of claim 4 further comprising a plurality of semiconductor packages stacked vertically wherein solder balls of an upper semiconductor package are coupled to lands of electrically conductive patterns of a lower semiconductor package which are exposed through land holes thereof.

6. The semiconductor package of claim 1 wherein the electrically conductive patterns are formed at a top surface of the insulative layer.

7. The semiconductor package of claim 6 further comprising a plurality of finger holes formed in the insulative layer corresponding to the bond fingers of the substrate.

8. The semiconductor package of claim 7 wherein the conductive bumps are connected to the bond finger exposed through the bond fingers.

9. The semiconductor package of claim 8 further comprising a plurality of semiconductor packages stacked vertically wherein solder balls of an upper semiconductor package are coupled to lands of electrically conductive patterns of a lower semiconductor package.

10. The semiconductor package of claim 8 further comprising a protective layer coupled to a top surface of the insulative layer.

11. The semiconductor package of claim 3 further comprising a die cavity formed near a center of the insulative layer of the substrate wherein the bond fingers extend to an inside part of the die cavity, the semiconductor die being located in the die cavity and the encapsulant being injected to the inside part of the die cavity forming an encapsulating portion.

12. The semiconductor package of claim 11 further comprising a plurality of semiconductor packages stacked vertically wherein solder balls of an upper semiconductor package are coupled to lands of electrically conductive patterns of a lower semiconductor package which are exposed through land holes thereof.

13. The semiconductor package of claim 11 wherein a protective layer is applied to the bottom surface of the insulative layer.

14. The semiconductor package of claim 1 further comprising a spacer having a predetermined thickness coupled to a bottom surface of the substrate.

15. The semiconductor package of claim 14 further comprising:
a plurality of spacer holes formed at the substrate corresponding to the spacer as an electrical conductor; and
solders coupled to the spacer holes of the substrate to stably fix the spacer to the substrate.

16. The semiconductor package of claim 15 wherein the spacers are coupled to the electrically conductive patterns of the substrate.

17. The semiconductor package of claim 16 further comprising a plurality of semiconductor packages stacked vertically wherein solder balls of an upper semiconductor package are coupled to lands of electrically conductive patterns of a lower semiconductor package.

18. The semiconductor package of claim 14 wherein the spacer is a nonconductor of electricity and is coupled to top and bottom surfaces of the substrate.

20. The semiconductor package of claim 14 wherein the spacer has a thickness approximately the same as that of the solder ball.

21. The semiconductor package of claim 18 further comprising a plurality of semiconductor packages stacked vertically wherein solder balls of an upper semiconductor package are coupled to lands of electrically conductive patterns of a lower semiconductor package.

22. A semiconductor package comprising:
a substrate of an approximate planar plate comprising an insulative layer, a plurality of electrically conductive patterns having bond fingers and lands formed at both surfaces of the insulative layer, the electrically conductive patterns being coupled to each other by means of electrically conductive vias, and insulating cover coats coated on the electrically conductive patterns;
semiconductor dies located at central portion of the substrate, the semiconductor die having a plurality of bond pads formed at one surface thereof;
a plurality of conductive bumps for coupling the bond pads of each semiconductor die to the bond fingers among the electrically conductive patterns formed at both surfaces of the substrate;
an encapsulating portion formed by applying an encapsulant to the bond pads of the semiconductor dies, the conductive bumps and the bond fingers of the electrically conductive patterns for protecting them from external environment; and
plurality of solder balls coupled to lands formed at one surface of the substrate.

23. The semiconductor package of claim 24 further comprising a plurality of semiconductor packages stacked vertically wherein solder balls of an upper semiconductor package are coupled to lands by electrically conductive patterns of a lower semiconductor package.

24. The semiconductor package of claim 22 wherein the semiconductor die further comprises a protective layer of a predetermined thickness formed at its back side.

25. A method for manufacturing semiconductor package comprising:
providing an insulative layer of an approximately planar plate comprising a die cavity formed at its center and a plurality of land holes formed at the periphery of the die cavity;
coupling a conductive thin layer to the insulative layer;
forming a substrate having a plurality of electrically conductive patterns by etching the conductive thin layer in predetermined shape to form a plurality of lands for covering the land holes and a plurality of bond fingers extending to the inside of the die cavity;
coupling an adhesive tape of an approximately planar plate to one surface of the substrate;
locating a semiconductor die having a plurality of bond pads inside the die cavity of the substrate;
coupling conductive bumps to the bond pads;
coupling the conductive bumps the bond fingers;
forming an encapsulating portion by applying an encapsulant to an inside of the die cavity to protect the bond pads of the semiconductor die, the conductive bumps and the bond fingers of the substrate from external environment;
removing the adhesive tape from the substrate; and
coupling a plurality of conductive balls to each land of the substrate.

26. The method of claim 25 further comprising stacking a plurality of semiconductor packages vertically wherein solder balls of an upper semiconductor package are coupled to lands of electrically conductive patterns of a lower semiconductor package which are exposed through land holes thereof.

27. A method for manufacturing semiconductor package comprising:
providing an insulative layer of an approximately planar plate comprising a die cavity formed at a center area and a plurality of land holes formed at a periphery of the die cavity;
bonding a conductive thin layer to the insulative layer to cover one surface of the insulative layer, the die cavity and the land holes;
forming a substrate having a plurality of electrically conductive patterns by etching the conductive thin layer in predetermined shape to form a plurality of lands for covering the land holes and a plurality of bond fingers extending to the inside of the die cavity;
forming a protective layer at a bottom surface of the insulative layer so the lands and the bond fingers are exposed to outside;
placing first and second semiconductor dies having a plurality of bond pads at upper and lower portions of the die cavity of the substrate respectively;
coupling conductive bumps to the bond pads of the first and second semiconductor dies;
coupling the conductive bumps on the bond fingers;
forming an encapsulating portion by applying an encapsulant to an inside of the die cavity to protect the bond pads of the first and second semiconductor dies, the conductive bumps and the bond fingers of the substrate from external environment; and
coupling a plurality of conductive balls to each land of the substrate.

28. The method of claim 29 further comprising stacking a plurality of semiconductor package vertically wherein solder balls of an upper semiconductor package are coupled to lands of electrically conductive patterns of a lower semiconductor package which are exposed through land holes thereof.

29. A method for manufacturing semiconductor package comprising:
providing a substrate comprising an insulative layer at a center area, a plurality of electrically conductive patterns having bond fingers and lands formed at both surfaces of the insulative layer, electrically conductive vias for electrically connecting the electrically conductive patterns formed at both surfaces of the insulative layer and insulating cover coats for coating the remaining regions of the electrically conductive patterns excepting the bond fingers and the lands;
forming an encapsulant at regions corresponding to the bond fingers formed at both surfaces of the substrate;
connecting first and second semiconductor dies having bond pads to surfaces of the encapsulant formed at both surface of the substrate respectively;
coupling conductive bumps to the bond pads of the first and second semiconductor dies and to the bond fingers through the encapsulant; and
coupling conductive balls on the lands of the substrate.

30. The method of claim 29 wherein the first and second semiconductor die further comprise die protective layers of a predetermined thickness formed at their back sides.

31. The method of claim 29 further comprising stacking a plurality of semiconductor packages vertically wherein solder balls of an upper semiconductor package are coupled to lands by electrically conductive patterns of a lower semiconductor package.
